(19) United States
(12) Patent Application Publication
(10) Pub. No.: US 2015/0109010 A1
(43) Pub. Date: Apr. 23, 2015

(54) ELECTROSTATIC DISCHARGE TEST APPARATUS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: Xiao-Lian HE, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/067,968

(22) Filed: Oct. 31, 2013

(30) Foreign Application Priority Data
Oct. 22, 2013 (CN) 2013104983869

(51) Int. Cl. G01R 31/16; G01R 31/14

(52) U.S. Cl. CPC G01R 31/16; G01R 31/14
USPC 324/750.14

(57) ABSTRACT

An electrostatic discharge (ESD) test apparatus includes a chamber with a supporting plate, a test bench mounted on the supporting plate, a first supporting bracket, a camera installed in the chamber, and a control apparatus. The first supporting bracket includes a first rail mounted on the supporting plate, a supporting pole movably connected to the first rail, a first adjusting pole movably installed to the supporting pole, an ESD gun rotatably installed to the first adjusting pole, a first driving assembly driving the supporting pole, a second driving assembly driving the first adjusting pole, and a third driving assembly driving the ESD gun to rotate. The camera captures images and further transmits the images to the control apparatus. The control apparatus controls the first driving assembly, the second driving assembly, and the third driving assembly.

### BACKGROUND

1. Technical Field

The present disclosure relates to an electrostatic discharge test apparatus.

2. Description of Related Art

Electrostatic discharge (ESD) test workstations generally require an operator to hold and move an ESD gun across products to be tested. However, the shaking of the hands may reduce the accuracy of the test result, and the performance of such manual operation is inefficient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an exemplary embodiment of an electrostatic discharge (ESD) test apparatus, wherein the ESD test apparatus includes two first supporting brackets and a second supporting bracket.

FIG. 2 is an enlarged view of one of the first supporting brackets of FIG. 1.

FIG. 3 is an enlarged view of the circled portion III of FIG. 2.

FIG. 4 is an enlarged isometric view of the second supporting bracket of FIG. 1.

FIG. 5 is similar to FIG. 3, but viewed from another perspective.

FIG. 6 is an enlarged view of the circled portion VI of FIG. 6.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

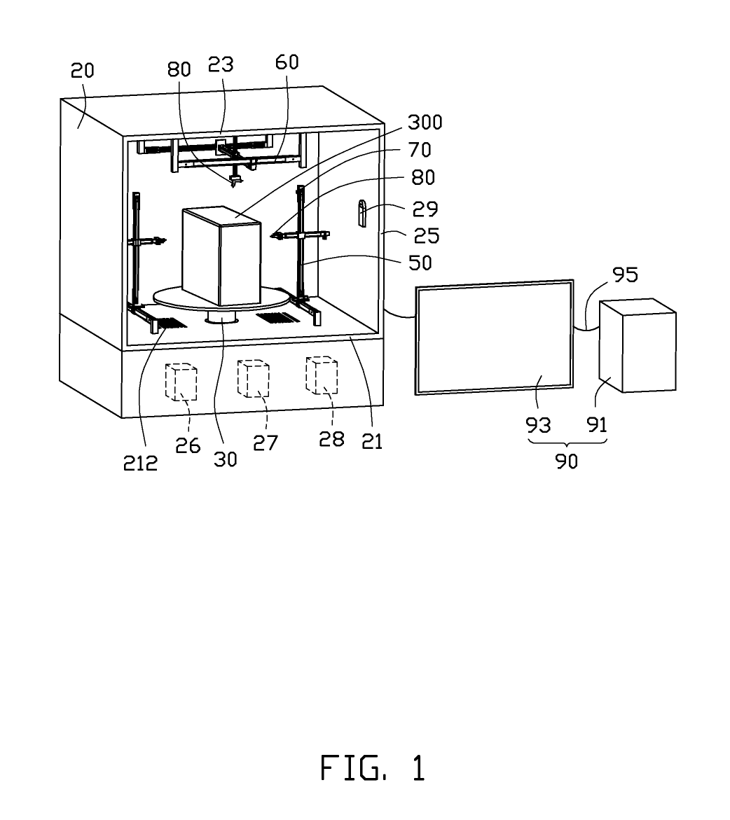

FIG. 1 shows an embodiment of an electrostatic discharge (ESD) test apparatus for testing objects 300. The objects 300 are information technology equipment, such as personal computers, liquid crystal displays, or mobile telephones. The ESD test apparatus includes a chamber 20, a test bench 30 received in the chamber 20, two opposite first supporting brackets 50, a second supporting bracket 60, a camera 70 mounted in the chamber 20, three ESD guns 80, and a control apparatus 90. In the embodiment, the control apparatus 90 is a computer, and the control apparatus 90 includes a host 91, a display 93, and a plurality of cables 95.

The chamber 20 includes a rectangular supporting plate 21, a top wall 23 opposite to the supporting plate 21, and a sidewall 25 connected between sides of the supporting plate 21 and the top wall 23. The supporting plate 21, the top wall 23, and the sidewall 25 cooperatively bound a hermetical space. The test bench 30 is mounted on a middle of the supporting plate 21. The first supporting brackets 50 are mounted on the supporting plate 21, at opposite sides of the test bench 30. The second supporting bracket 60 is mounted to an inner surface of the top wall 23, and faces the test bench 30.

The chamber 20 further includes an air-conditioning 26, a humidifier 27, and a dehumidifier 28 all located below the supporting plate 21. The supporting plate 21 defines a plurality of vents 212. A hygrothermograph 29 is mounted on an inner surface of the sidewall 25.

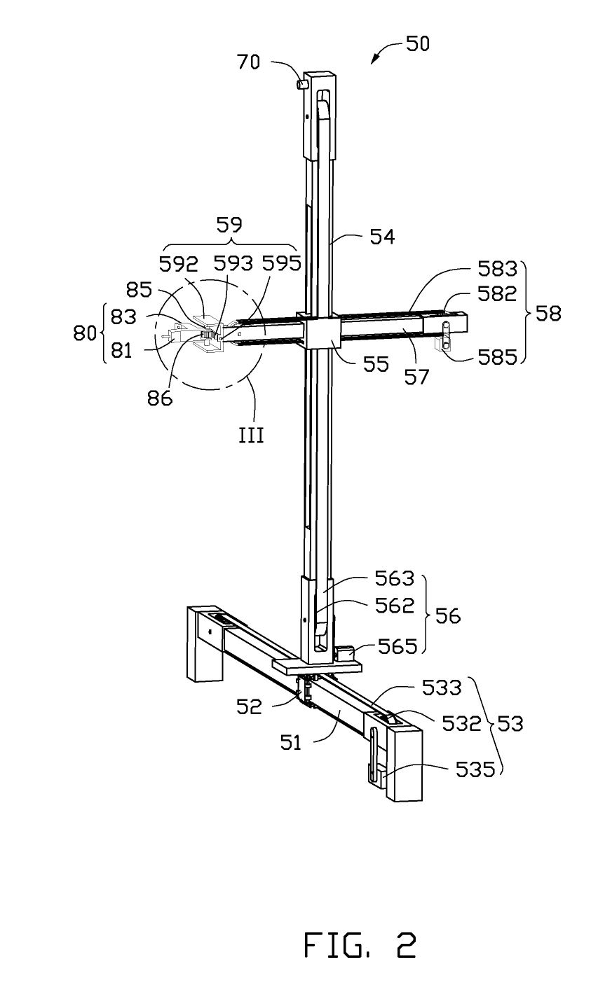

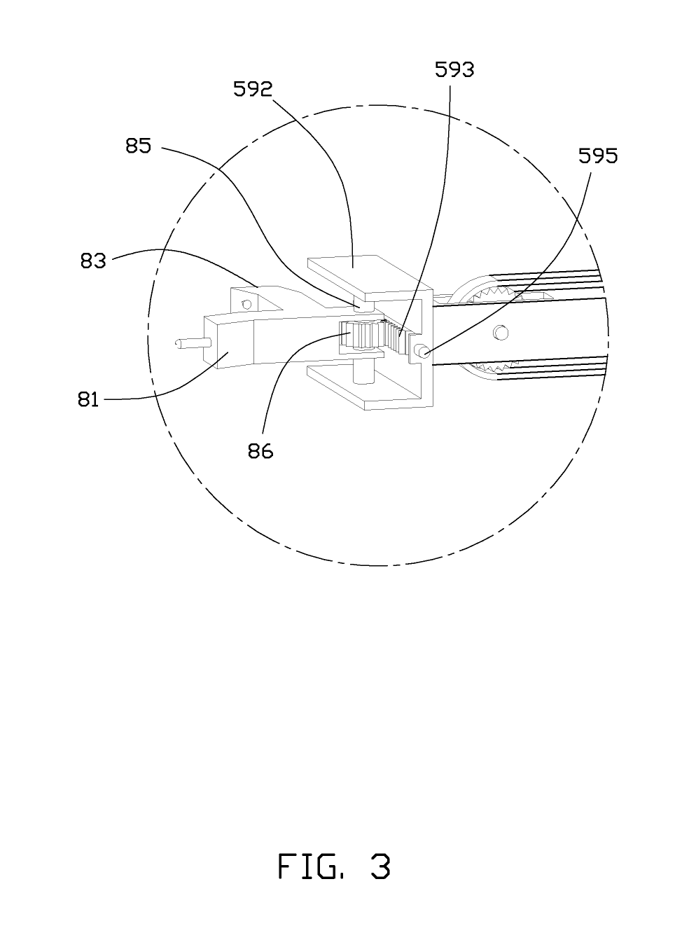

FIGS. 2 and 3 show each first supporting bracket 50 includes a first rail 51 mounted on the supporting plate 21. A first sliding joint 52 slidably fitted about the first rail 51, a first driving assembly 53 driving the first sliding joint 52 to slide along the first rail 51. A supporting pole 54 mounted on the first sliding joint 52 and extending along a direction perpendicular to a sliding direction of the first sliding joint 52. A second sliding joint 55 slidably fitted about the supporting pole 54. A second driving assembly 56 driving the second sliding joint 55 to slide along the supporting pole 54, a first adjusting pole 57 slidably fitted about the second sliding joint 55 and a first end of which is facing the test bench 30. A third driving assembly 58 driving the first adjusting pole 57 to slid toward the object 300 supported on the test bench 30, and a rotating assembly 59 installed at the first end of the first adjusting pole 57 adjacent to the test bench 30.

The first driving assembly 53 includes two wheels 532 rotatably installed at two opposite ends of the first rail 51, a belt 533 surrounding the wheels 532, and a first motor 535 mounted to one of the ends of the first rail 51 and driving the wheels 532 to rotate. The first sliding joint 52 is fixed to a point of the belt 533 and moves with the belt 533. Therefore, the wheels 532 are driven by the first motor 535 to rotate, the belt 533 moves to make the first sliding joint 52 move along the first rail 51.

The second driving assembly 56 includes two wheels 562 rotatably installed at two opposite ends of the supporting pole 54, a belt 563 surrounding the wheels 562, and a second motor 565 mounted to a lower ends of the supporting pole 54 and driving the wheels 562 to rotate. The second sliding joint 55 is fixed to a point of the belt 563 and moves with the belt 563. Therefore, the wheels 562 are driven by the second motor 565 to rotate, the belt 563 moves to make the second sliding joint 55 move along the supporting pole 54.

The third driving assembly 58 includes two wheels 582 rotatably installed at two opposite ends of the first adjusting pole 57, a belt 583 surrounding the wheels 582, and a third motor 585 mounted to a second end of the first adjusting pole 57 and driving the wheels 582 to rotate. The second sliding joint 55 is fixed to a point of the belt 583. Therefore, the wheels 582 are driven by the third motor 585 to rotate, the wheels 582 move the belt 583, thereby moving the first adjusting pole 57 toward or away from the object 300. The camera 70 is mounted at an upper end of the supporting pole 54. The first motor 535, the second motor 565, the third motor 585, and the camera 70 are electrically coupled to the control apparatus 90 by the cables 95.

The rotating assembly 59 includes a shell 592 fixed to the first end of the first adjusting pole 57, a rack 593 slidably installed in the shell 592, and a cylinder 595 mounted to the shell 592 and driving the rack 593 to slide along the rack 593. A slide direction of the rack 593 is the same as the movement direction of the first adjusting pole 57. The cylinder 595 is electrically coupled to the control apparatus 90.

Each ESD gun 80 is substantially T-shaped, and the ESD gun 80 includes an air gun head 81 and a contacting gun head 83 angled from the air gun head 81 in a substantially perpendicular manner. Two opposite shafts 85 protrude out from an end of the air gun head 81, and are rotatably connected to the shell 592. A protruding direction of the shafts 85 is perpendicular to a protruding direction of the contacting gun head 83. A gear wheel 86 is mounted to the end of the air gun head 81, and engages with the rack 593. The cylinder 595 drives the rack 593 to slide, the rack 593 drives the gear wheel 86 to rotate, to allow the air gun head 81 or the contacting gun head 83 to align with the object 300.

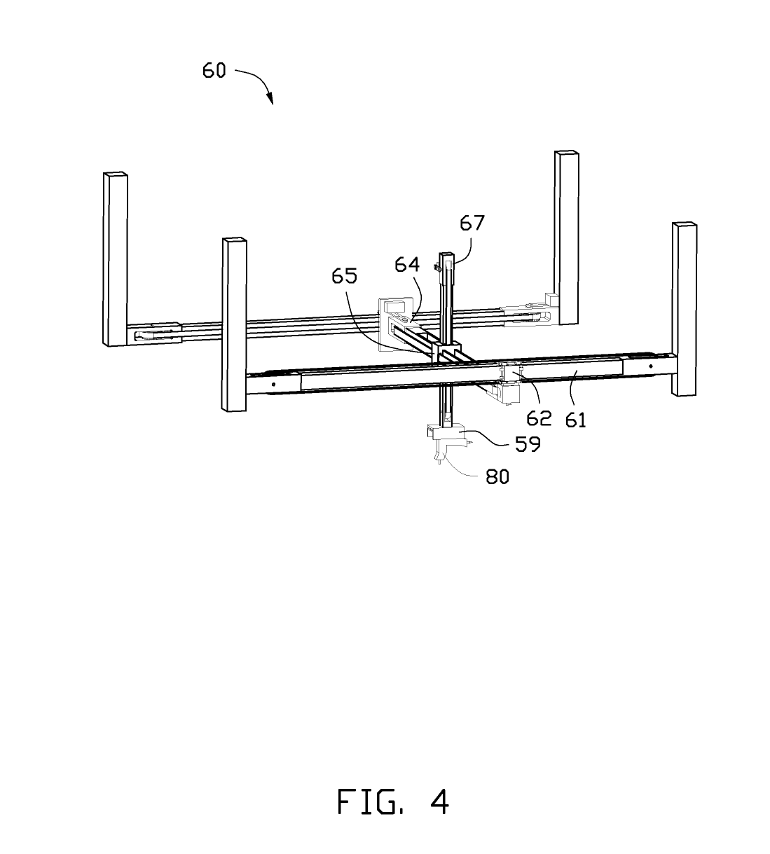

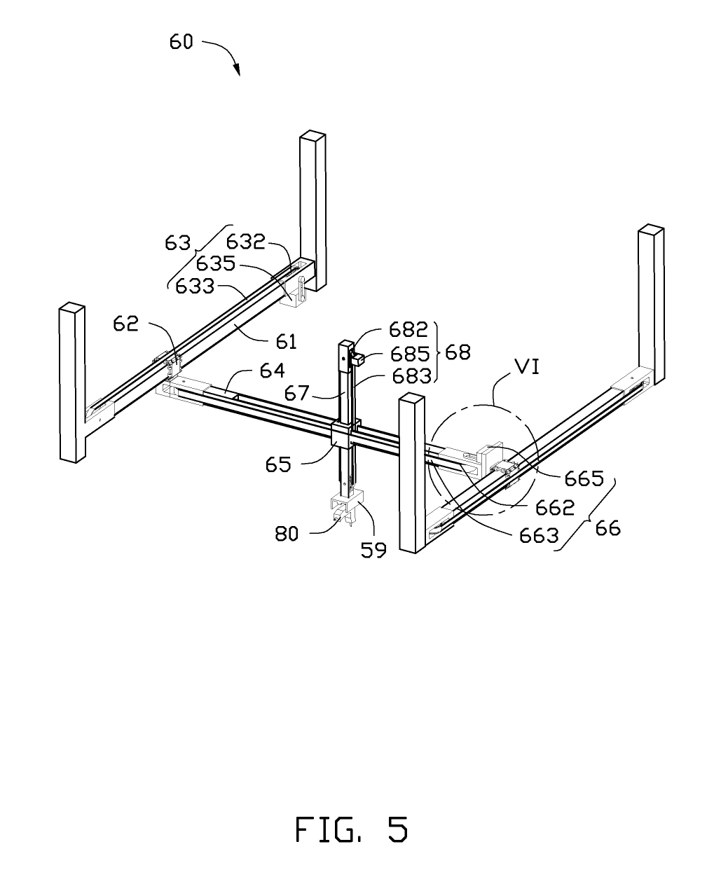

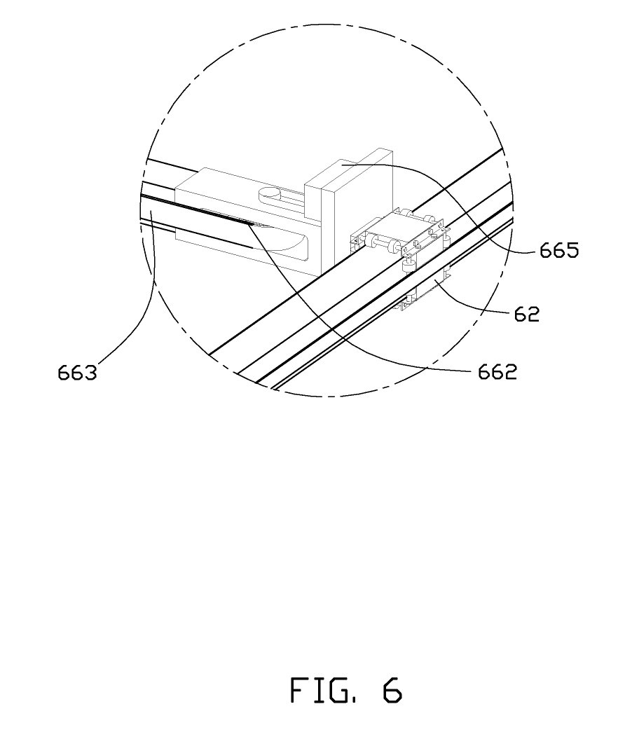

FIGS. 4-6 show the second supporting bracket 60 includes two opposite and spaced second rails 61 mounted on and spaced from an inner surface of the top wall 23.

Two third sliding joints 62 slidably fitted about the second rails 61, a fourth driving assembly 63 driving the third sliding joints 62 to slide along the second rails 61. A sliding pole 64 mounted to the third sliding joints 62 with two opposite ends, a fourth sliding joint 65 slidably fitted about the sliding pole 64. A fifth driving assembly 66 driving the fourth sliding joint 65 to slide along the sliding pole 64, a second adjusting pole 67 slidably extending through the fourth sliding joint 65 and the sliding pole 64 up and down, and a sixth driving assembly 68. A bottom end of the second adjusting pole 67 faces the test bench 30, and the sixth driving assembly 68 drives the second adjusting pole to slide toward the test bench 30. Another rotating assembly 59 is mounted to the bottom end of the second adjusting pole 67, and one of the electrostatic guns 80 is installed to the rotating assembly 59.

The fourth driving assembly 63 includes four wheels 632 rotatably installed at two opposite ends of the second rails 61. Two belts 633 each surrounding two wheels 632 installed at a corresponding second rail 61, and a fourth motor 635 mounted to one of the ends of one of the second rails 61 and driving the third sliding joints 62 to move along the second rails 61. The fifth driving assembly 66 includes two wheels 662 rotatably installed at two opposite ends of sliding pole 64, a belt 663 surrounding the wheels 662, and a fifth motor 665 mounted to one of the ends of the sliding pole 64 and driving the fourth sliding joint 65 to move along the sliding pole 64. The sixth driving assembly 68 includes two wheels 682 rotatably installed at top and bottom ends of the second adjusting pole 67, a belt 683 surrounding the wheels 682, and a sixth motor 685 mounted to the top end of the second adjusting pole 67 and driving the second adjusting pole 67 to move toward the object 300. The fourth motor 635, the fifth motor 665, and the sixth motor 685 are electrically coupled to the control apparatus 90.

In use, the object 300 is supported on the test bench 30, and the camera 70 captures images of the object 300. The images of the camera 70 are transmitted to the host 91. The host 91 processes and analyzes the images of the camera 70, and chooses a plurality of test points on the object 300 to be discharged. The host 91 controls the air-conditioning 26, the humidifier 27, and the dehumidifier 28 to operate or not, to make a humidity in the chamber 20 satisfy the requirement. The host 91 also controls the hygrothermograph 29 to display the humidity. The host 91 controls the first motor 535, the second motor 565, the third motor 585, the fourth motor 635, the fifth motor 665, and the sixth motor 685 to move the ESD guns 80 to test the corresponding test points on the object 300. The host 91 controls the cylinder 595 to rotate the ESD guns 80, to allow the air gun head 81 or the contacting gun head 83 to test the object 300. The test results are displayed through the display 93.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. An electrostatic discharge (ESD) test apparatus, comprising:
a chamber comprising a supporting plate;
a test bench installed on the supporting plate for supporting an object;
a first supporting bracket comprising a first rail mounted on the supporting plate and at a side of the test bench, a supporting pole slidably connected to the first rail and perpendicular to the supporting plate, a first adjusting pole slidably connected to the supporting pole and extending toward the object, a first ESD gun rotatably installed at an end of the first adjusting pole facing the test bench, a first driving assembly driving the supporting pole to move along the first rail, a second driving assembly driving the first adjusting pole to move along the supporting pole, a third driving assembly driving the first adjusting pole to move toward the object, and a first rotating assembly driving the first ESD gun to rotate;
a camera mounted in the chamber, and used to pickup images of the object; and
a control apparatus electrically coupled to the first driving assembly, the second driving assembly, the third driving assembly, the rotating assembly, and the camera;
wherein the images of the camera are transmitted to the control apparatus, the control apparatus controls the first driving assembly, the second driving assembly, the third driving assembly, the rotating assembly for testing the object.

2. The ESD test apparatus of claim 1, wherein the test bench is installed on a middle of the supporting plate.

3. The ESD test apparatus of claim 1, further comprising an air-conditioning, a humidifier, and a dehumidifier mounted to the chamber and below the supporting plate, wherein the supporting plate defines a plurality of vents.

4. The ESD test apparatus of claim 1, wherein the first supporting bracket further comprises a first sliding joint slidably fitted about the first rail, a bottom end of the supporting pole is mounted on the first sliding joint.

5. The ESD test apparatus of claim 4, wherein the first supporting bracket further comprises a second sliding joint slidably fitted about the supporting pole, the first adjusting pole is slidably fitted about the second sliding joint and perpendicular to the supporting pole.

6. The ESD test apparatus of claim 4, wherein the first driving assembly comprises two first wheels rotatably installed at two opposite ends of the first rail, a first belt surrounding the first wheels, and a first motor mounted to the first rail to drive the first sliding joint to move along the first rail, the first motor is electrically coupled to the control apparatus.

7. The ESD test apparatus of claim 5, wherein the second driving assembly comprises two second wheels rotatably installed at two opposite ends of the supporting pole, a second belt surrounding the second wheels, and a second motor mounted to the supporting pole to drive the second sliding joint to move along the supporting pole, the second motor is electrically coupled to the control apparatus.

8. The ESD test apparatus of claim 5, wherein the third driving assembly comprises two third wheels installed at two opposite ends of the first adjusting pole, a third belt surrounding the third wheels, and a third motor mounted to the first adjusting pole to drive the first adjusting pole to move toward the object, the third motor is electrically coupled to the control apparatus.

9. The ESD test apparatus of claim 1, wherein the rotating assembly comprises a shell mounted to the end of the first adjusting pole adjacent to the test bench, a rack slidably installed in the shell, and a cylinder mounted to the shell to drive the rack to slide along a direction perpendicular to the first adjusting pole, the first ESD gun comprises a gear wheel engaged with the rack, the cylinder is electrically coupled to the control apparatus.

10. The ESD test apparatus of claim 9, wherein the first ESD gun is substantially T-shaped, and comprises an air gun head, a contacting gun head angled from the air gun head, and two opposite shafts protruding out from an end of the air gun head, the shafts are rotatably connected to the shell, the gear wheel is mounted to the end of the air gun head.

11. The ESD test apparatus of claim 1, further comprising a second supporting bracket mounted to an inner surface of a top wall of the chamber, wherein the second supporting bracket comprises two opposite and spaced second rails mounted to the top wall, a sliding pole slidably installed between the second rails, a fourth driving assembly driving the sliding pole to slide along the second rails, a second adjusting pole slidably mounted to the sliding pole, a fifth driving assembly driving the second adjusting pole to slide along the sliding pole, a sixth driving assembly driving the second adjusting pole to slide toward the test bench, a second rotating assembly mounted to an end of the second adjusting pole adjacent to the object, and a second ESD gun installed to the rotating assembly, wherein the fourth driving assembly, the fifth driving assembly, the sixth driving assembly, and the second rotating assembly are electrically coupled to the control apparatus.

12. The ESD test apparatus of claim 11, wherein the second supporting bracket further comprises two third sliding joints slidably fitted about the second rails, two opposite ends of the sliding pole are mounted to the third sliding joints.

13. The ESD test apparatus of claim 11, wherein the second supporting bracket further comprises a fourth sliding joint slidably fitted about the sliding pole, the second adjusting pole is slidably fitted about the fourth sliding joint in a direction perpendicular to the sliding pole.

14. The ESD test apparatus of claim 12, wherein the fourth driving assembly comprises four fourth wheels rotatably installed at two opposite ends of the second rails, two fourth belts each surrounding two fourth wheels installed at a corresponding second rail, and a fourth motor mounted to one of the second rails to drive the third sliding joint to move along the second rails, the fourth motor is electrically coupled to the control apparatus.

15. The ESD test apparatus of claim 13, wherein the fifth driving assembly comprises two fifth wheels rotatably installed at two opposite ends of the sliding pole, a fifth belt surrounding the fifth wheels, and a fifth motor mounted to the sliding pole to drive the fourth sliding joint to move along the sliding pole, the fifth motor is electrically coupled to the control apparatus.

16. The ESD test apparatus of claim 13, wherein the sixth driving assembly comprises two sixth wheels installed at two opposite ends of the second adjusting pole, a sixth belt surrounding the sixth wheels, and a sixth motor mounted to the second adjusting pole to drive the second adjusting pole to move toward the object, the sixth motor is electrically coupled to the control apparatus.
